(19) United States
(12) Patent Application Publication
(10) Pub. No.: US 2025/0383605 A1
(43) Pub. Date: Dec. 18, 2025

(54) ALKYLSULFONIC ACID DEVELOPER COMPOSITIONS AND PATTERNING METHODS FOR ORGANOMETALLIC OXIDE PHOTORESISTS

(71) Applicant: Inpria Corporation, Corvallis, OR (US)

(72) Inventors: Matthew Voss, Corvallis, OR (US); Kai Jiang, Corvallis, OR (US)

(21) Appl. No.: 19/240,246

(22) Filed: Jun. 17, 2025

Related U.S. Application Data
(60) Provisional application No. 63/661,293, filed on Jun. 18, 2024.

(51) Int. Cl. G03F 7/32; G03F 7/004; G03F 7/38; G03F 7/40

(52) U.S. Cl. CPC G03F 7/32; G03F 7/0042; G03F 7/38; G03F 7/40

(57) ABSTRACT

Patterning of organometallic radiation sensitive compositions is facilitated using alkylsulfonic acid developer compositions and patterning methods. The alkylsulfonic acid developer compositions comprise an alkylsulfonic acid composition and a solvent, such as water or an organic solvent. In some embodiments, contact with an alkylsulfonic acid developer composition can be performed on an organometallic composition having a latent image to form a developed, physical pattern. The latent image may be formed by irradiation of an organometallic composition with a pattern of radiation, such as EUV radiation. In some embodiments, contact with an alkylsulfonic acid developer composition can be performed on an organometallic composition having a physical pattern to form a higher contrast, descummed pattern. Methods for patterning with an alkylsulfonic acid developer composition may include heating prior to and/or after contacting with the alkylsulfonic acid developer composition as well as resting for selected periods of time.

### CROSS REFERENCE TO RELATED APPLICATIONS

This application claims priority to copending U.S. provisional patent application 63/661,293 filed Jun. 18, 2024 to Voss et al., entitled “Alkylsulfonic Acid Developers for Organometallic Oxide Photoresists,” incorporated herein by reference.

### FIELD OF THE INVENTION

The invention relates to development of organometallic based patterning compositions, especially organotin compositions, following irradiation to form a physically patterned material, in particular using a developer solution comprising dissolved alkylsulfonic acid. The invention further related to decreasing defectivity of a developed pattern in an organometallic material using a rinse with a solution comprising dissolved alkylsulfonic acid.

### BACKGROUND

Semiconductor lithography is a complex and critical technology used to fabricate myriad and diverse devices that have dominated and transformed the modern world beginning in the 20^{th} century. The semiconductor lithographic process is generally an iterative process involving repeated steps of deposition, patterning, and etching of many layers and materials to form the desired devices. As technology advances and new, increasing demands and requirements are placed upon each generation of devices, the need to develop processes and materials that are able to meet these requirements increases. One of the critical materials used in the semiconductor lithographic process is the photoresist in which an initial pattern is formed by exposure to radiation and is then subsequently transferred into the underlying substrate.

Organometallic photoresists have been shown to be promising materials for use in current and next-generation semiconductor lithography processing due to their ability to form high-resolution, high etch resistance, and high-fidelity patterns. These organometallic systems generally operate through radiation exposure-mediated formation of condensed oxide networks that drive contrast between irradiated (i.e., exposed) and non-irradiated (i.e., unexposed) regions of the material. A development process can then be used that can selectively remove the irradiated or the non-irradiated material to realize a physical pattern of material based on a latent image formed by the pattern of radiation.

### BRIEF DESCRIPTION OF THE DRAWINGS

FIG. 1 is a flowchart of a patterning process for a radiation patternable organometallic coating utilizing an alkylsulfonic acid developer solution.

FIG. 2 is a flowchart of a patterning process for a radiation patternable organometallic coating utilizing an alkylsulfonic acid developer solution ‘wet descum’ to improve the fidelity of an initial negative tone pattern formed during the first development step.

FIG. 3. is an illustrative plot of the number of defects as a function of critical dimension for two resists A and B, showing the difference in defect window size.

FIG. 4 is an illustrative plot of a generic negative-tone contrast curve, highlighting important values and/or regions.

FIG. 5 is a flowchart of a patterning process for a radiation patternable organometallic coating utilizing an alkylsulfonic acid developer solution and comprising two post exposure bake (PEB) steps separated by a rest step.

FIG. 6 is a set of four contrast curves for organotin photoresist coated wafers developed using an alkylsulfonic acid developer solution and processed with varying PEB schemes and temperatures.

FIG. 7. is a set of three contrast curves for organotin photoresist coated wafers: RCE developed in 2-heptanone, and RC1 and RC2 developed in 2-heptanone followed by a second post exposure bake (PEB2) and a second development step with an alkylsulfonic acid developer solution.

FIG. 8 is a plot of number of defects per image as a function of critical dimension for an organotin photoresist coating developed with an acetic acid (AA) developer, indicated by circle markers, and a methanesulfonic acid (MSA) developer, indicated by square markers.

FIG. 9 is a plot of film thickness as a function of radiation dose for organotin photoresist coatings developed by contacting with an aqueous methanesulfonic developer solution for 15, 30, or 90 seconds.

FIG. 10 is a set of three EUV exposure contrast curves for organotin photoresist coated wafers: E developed in 0.87 M acetic acid in PGMEA and indicated by circle markers, F developed in 0.05 M MSA in H₂O and indicated by square markers, and G developed in 0.10 MSA in H₂O and indicated by triangle markers.

### SUMMARY OF THE INVENTION

One aspect of the invention pertains to a method of developing an organometallic material on a surface of a substrate and having a virtual image. The method comprises contacting the organometallic material with an alkylsulfonic acid developer solution comprising an alkylsulfonic acid composition and a solvent.

In a further aspect, the invention pertains to a method for patterning an organometallic material having a latent image formed by irradiation on a substrate. The method comprises heating the organometallic material at a temperature from about 45° C. to about 250° C. to perform a post exposure bake; and contacting the organometallic material with an alkylsulfonic acid developer solution comprising a solvent and an alkylsulfonic acid composition dissolved in the solvent.

In an additional aspect, the method invention pertains to a method for improving a pattern formed in an organometallic material. The method comprises descumming a patterned organometallic material on a substrate surface with a developer solution to remove additional irradiated material which can reduce defectivity of the pattern, wherein the developer solution comprises a solvent and an alkylsulfonic acid composition dissolved in the solvent.

In a further aspect, the invention pertains to a patterning solution system comprising a first patterning solution comprising an organic solvent; and a second patterning solution comprising a second solvent and an alkylsulfonic acid.

In another aspect, a patterning process comprises first providing a substrate coated with a radiation patternable organometallic material, exposing onto the organometallic coating a pattern of radiation to form a latent image comprising exposed and unexposed regions, subjecting the organometallic coated substrate to a first post exposure bake step, developing the organometallic coated substrate using an organic solvent developer composition to form an initial pattern, then subjecting the coated substrate to a post development bake step before a second development step in which the coated substrate is contacted with an alkylsulfonic acid developer solution comprising an alkylsulfonic acid composition and a solvent to preferentially remove residual unexposed material, and then optionally subjecting the organometallic coated substrate to a hard bake (HB).

In a further aspect, a patterning process comprises first providing a substrate coated with a radiation patternable organometallic material, exposing onto the organometallic coating a pattern of radiation to form a latent image comprising exposed and unexposed regions, subjecting the organometallic coated substrate to a first post exposure bake step, resting the coated substrate at ambient temperature, subjecting the coated substrate to a second post exposure bake step, developing the coated substrate by contacting with an alkylsulfonic acid developer solution comprising an alkylsulfonic acid composition and a solvent to preferentially remove the unexposed regions in a negative tone development process, and optionally subjecting the coated substrate to a hard bake (HB).

### DETAILED DESCRIPTION OF THE INVENTION

Improved development of radiation induced virtual images within organometallic photoresist material can be achieved using solutions of alkylsulfonic acid as a liquid developer that can be used for an initial development of a virtual image or for pattern improvement. Patterning of organometallic photoresists, and specifically organotin, generally involves selectively removing the non-irradiated regions, which are hydrophobic and carbon-rich, or the irradiated regions, which are hydrophilic and carbon-poor, from the substrate. Organic solvent compositions are generally used to facilitate negative-tone patterning where the non-irradiated material is selectively removed from the substrate, whereas aqueous-based compositions, generally at an alkaline pH, have generally been shown to operate as positive-tone developers where the irradiated material is selectively removed from the substrate. As described herein, a developer, either aqueous or nonaqueous, with dissolved alkylsulfonic acid can selectively remove non-irradiated material while leaving irradiated material in a negative tone development process. The negative tone developer based on alkylsulfonic acid can be effective in a single development step or in a two-step or multi-step development as a second developer or post-development treatment for pattern improvement.

Organometallic photoresist compositions are a class of materials used in the field of semiconductor manufacturing and photolithography. Like conventional polymer-based resists, they serve as a radiation-patternable layer that can be exposed to a pattern of radiation to form a latent image comprising exposed and unexposed regions and selectively developed to create a physical mask on a substrate that corresponds to the pattern of radiation, and which then can guide the subsequent etching and deposition processes used to fabricate semiconductor devices. Organometallic photoresists are typically composed of materials that are metal oxide based with organic ligands (organometallic composition). The solubility of the organometallic photoresists in developer solutions and/or resistance to removal by gaseous developers can be altered when exposed to radiation, such as UV light, electron beams, or extreme ultraviolet (EUV) light. As described further below, organotin photoresists are organometallic photoresists that have been developed into a foundational commercial technology for EUV photolithography defining the capabilities of the field.

The non-irradiated organometallic material is relatively rich in organic material and has corresponding solubility properties. The solubility properties change markedly upon irradiation resulting in a desirable property contrast between the irradiated and non-irradiated materials. Irradiation decreases the organic component of the material while increasing the metal oxide character, condensing the material. As described further below, Applicant has previously worked on improved developers for organometallic patterning compositions, and organic solvent compositions with highly polar additives, such as carboxylic acids, have been shown to lead to improved patterning for organotin resists over similar additive free solvent compositions. While not wanting to be limited by theory, it is believed that acid compositions can enhance the removal of non-irradiated material through increased coordination, complexation, and reaction with the organometallic material. Similarly, the use of water as an additive may improve the development. Developer solutions with the alkylsulfonic acid compositions described herein can further enhance removal of non-irradiated and lightly irradiated material. The combination of an organic ligand constituent and the strong acidity of the alkylsulfonic acid is observed to allow for improved development of the organometallic material, while surprisingly not removing significant amounts of irradiated material at appropriate irradiation doses. It is further surprising that this solubility contrast can be observed with either aqueous or non-aqueous solutions of alkylsulfonic acid as developer. The increase in solubility contrast manifests itself in improvement of pattern quality, which can be evaluated using contrast curves as described below.

Exposure of organotin photoresists to radiation generally results in the cleavage of Sn—C bonds and the loss of organic content in the exposed regions. The unexposed regions generally retain at least a substantial amount of their Sn—C bonds and organic content. Thus, there exists a significant chemical contrast between the unexposed and exposed regions. The alkylsulfonic acid developers described herein can selectively remove the unexposed regions of the organotin photoresist. Owing to their organic content, the alkylsulfonic acids can readily interact with and dissolve the unexposed and hydrophobic regions of the organotin photoresist materials. The acidity of the alkylsulfonic acids can also enhance the dissolution and removal of the unexposed and lightly exposed material to produce desirable contrast curves, as exemplified herein. Surprisingly, even in aqueous solutions, the developer solutions with alkylsulfonic acids do not appreciably dissolve the irradiated organometallic resists.

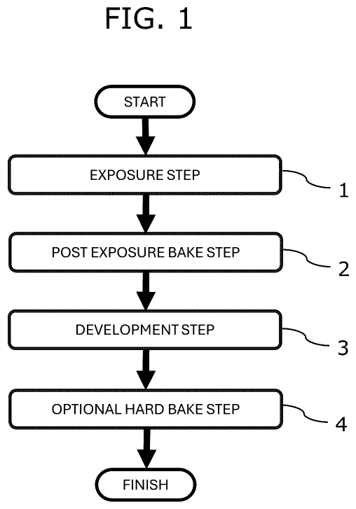

The steps for a patterning process utilizing an alkylsulfonic acid developer solution are depicted in FIG. 1. After forming a patternable film on a substrate, a radiation pattern is projected on a radiation patternable organometallic coated substrate in exposure step 1 to form an irradiated coated substrate comprising a latent image of exposed and unexposed regions, then subsequently baked in post exposure bake step 2. The coated substrate is then contacted with an alkylsulfonic acid developer solution in development step 3 to preferentially remove the unexposed regions and optionally subjected to hard bake step 4. The finished patterned substrate can then be used as a physical mask to guide further processing, such as through etching through the mask and/or deposition through the mask. In a commercial process environment, the patterning is generally repeated many times to form devices in fabrication facilities.

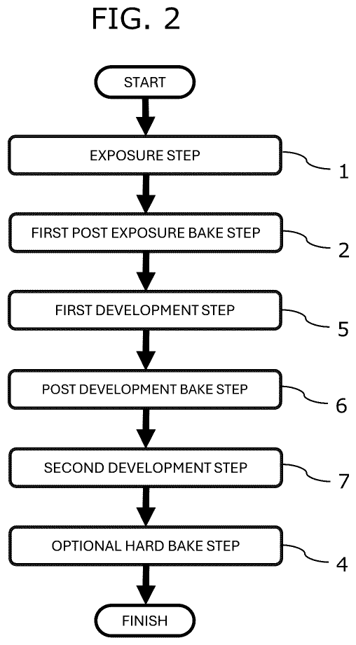

The alkylsulfonic acid developer solution can also be used as a second developer composition following a first development of the organotin photoresist coating with a first developer, in a process that can be termed a post development treatment, descumming, or a ‘wet descum’ using terminology familiar in the art. FIG. 2 depicts the order of steps for a method of patterning an organometallic coated substrate with a wet descum step. A radiation pattern is projected on a radiation patternable coated substrate in exposure step 1, as in FIG. 1, to form an irradiated coated substrate comprising a latent image of exposed and unexposed regions. The irradiated organometallic coating is then baked in a first post exposure bake step 2 and first developed to remove the bulk of the unexposed material in a first development step 5 to form an initial developed pattern. The first development step can be performed with a first liquid developer composition or in a dry development step, as described further below. In some embodiments where the first developer solution does not comprise an alkylsulfonic acid, the developer solution can be an organic solvent, such as the solvents used to form the precursor solutions, or a blend of solvents.

In general, developer selection can be influenced by solubility parameters with respect to the coating material, both irradiated and non-irradiated, as well as developer volatility, flammability, toxicity, viscosity and potential chemical interactions with other process material. In particular, suitable developers include, for example, aromatic compounds (e.g., benzene, xylenes, toluene), esters (e.g., propylene glycol monomethyl ester acetate (PGMEA), ethyl acetate, ethyl lactate, n-butyl acetate, butyrolactone), alcohols (e.g., 4-methyl-2-pentanol, 1-butanol, isopropanol, 1-propanol, methanol), ketones (e.g., methyl ethyl ketone, acetone, cyclohexanone, 2-heptanone, 2-octanone), ethers (e.g., tetrahydrofuran, dioxane, anisole), mixtures thereof or the like. Improved developer compositions have been described in published U.S. Patent Application No.: 2020/0326627 to Jiang et al., entitled “Organometallic Photoresist Developer Compositions and Processing Methods,” incorporated herein by reference. Improved developer solutions generally comprise a reference organic solvent composition and an additive composition having a higher polarity and/or hydrogen-bonding character than the reference solvent composition. In one example, an improved developer composition can comprise PGMEA and acetic acid at a concentration from about 0.1% by weight to about 10% by weight or any subrange of concentrations within the explicit range.

In some embodiments, an alkylsulfonic acid can be used in both development steps. Additional descum steps can be used if desired, and an optional inert rinse can be performed to remove residual material from the surface. In some embodiments, the initial developed pattern is then baked in a post-development bake (PDB) step 6 to remove residual solvent and to drive additional densification of the initial pattern material. The initial pattern is then further refined in a second development step 7 wherein the coated substrate is contacted with an alkylsulfonic acid developer solution to remove additional material and to improve the fidelity of the pattern. Then, hard bake (HB) step 4 can then be performed, if desired. While both a PDB step and a HB step are performed after a development step, these are differentiated from each other by a PDB step being performed prior to a further development/descum step, which can influence desired bake conditions such as temperature and length of time.

Applicant has previously demonstrated use of a “wet descum” step where a second development is performed after a first development and, optionally, a post-development bake, but in this work, the second development was performed with a positive tone developer after a first development with a negative tone developer. See, U.S. Pat. No. 11,480,874 to Kocsis et al., entitled “Patterned Organometallic Photoresists and Methods of Patterning,” incorporated herein by reference. The use of a second development step with a developer solvent has been shown to improve a developed pattern, with respect to pattern quality, reduction of defects, and resolution, with some loss of patterned material influencing dimensions of patterned features. With respect to use of a second development step with a negative tone developer, see published U.S. patent application 2020/0326627 to Jiang et al. (hereinafter the '627 application), entitled “Organometallic Resist Developer Compositions and Processing Methods,” incorporated herein by reference. The results from a wet descum using a second negative tone developer were significantly dependent on the selection of the developer solution. Herein, developer solutions comprising an alkylsulfonic acid composition are described, as are desirable methods for developing organometallic resists in a one step or two step wet development process utilizing the alkylsulfonic acid developer solution.

A second development step generally removes additional material to improve the pattern by appropriate metrics. While a second development step has been referred to as a rinse in some contexts prior to the present work, on further reflection, this terminology has the potential for confusion, although clear to a person of ordinary skill in the art in context. In particular, a rinse can refer to the use of a neutral liquid, or gas, that simply facilitates removal of the developer and material dissolved by the developer, where the rinse does not itself further dissolve any significant amount of material. Thus, a rinse liquid generally has little or no effect if it were used as a developer. In the Examples below, deionized water is used as a rinse liquid. Thus, as used herein, rinse refers to use of a neutral liquid that does not dissolve a significant amount of further patterning material, whether irradiated or non-irradiated. A second development step can be referred to as a “wet descum”, where scum in the art refers to residual patterning material on the substrate remaining after development in regions in which patterning material was substantially removed, which can in some cases result in defects. One such example of these defects are microbridges wherein two distinct patterned features are defectively connected by residual patterning material to form one continuous patterned feature. These defects can be undesirable and can compromise the functionality of the integrated circuit devices in which they are present.

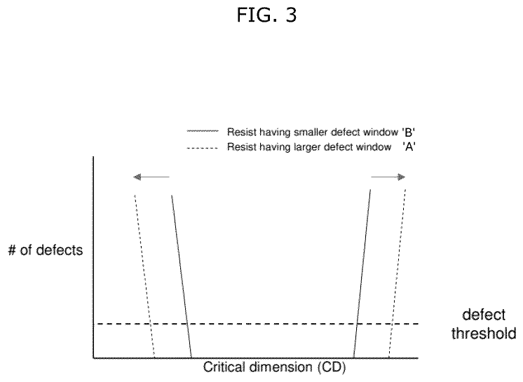

Due to desirable developer performance, the alkylsulfonic acid developer compositions can lead to improved defectivity performance of organometallic photoresists relative to some more conventional developers, and defect windows can be improved. Defect windows are commonly known in that art and can be generally described by the range of critical dimensions (CDs) that can be patterned at a selected pitch for a given resist and/or as a process without the number of defects above some threshold value. The critical dimension is the resulting feature size, such as the width of a stripe, for a particular resist coating at a specific irradiation dose and regular pattern, So for a particular resist film, the CD can be varied by correspondingly varying the irradiation dose. In one exemplary process for generating a defect window plot, a line-space pattern can be exposed via radiation on a photoresist at a range of radiation doses to yield a corresponding range of CDs which can be measured along with the number of defects and the results can be plotted. Two generic defect windows are shown in FIG. 3, which are plots of the number of defects vs. CD for two different resists wherein one resist process ‘A’ shows a wider range of CDs for which the number of defects is below a threshold value than for the other resist process ‘B’. At larger CDs, the features are generally overexposed, and opposing line edges are closer together. Since line edges are closer together, defects, such as microbridges, can more easily form spanning between line edges. Overexposure of the features can also lead to an increased number of photons falling in the nominal spaces of the pattern (i.e., material meant to be removed by development) which can lead to insoluble exposure products and can manifest as defects such as scum as well as microbridges. At smaller CDs the printed lines are generally under-exposed, and defects such as line breaks can form. Therefore, a wide defect window generally represents a process that results in low defects across a wide range of CDs. While FIG. 3 displays widening of the process window at both higher CD and at lower CD, a widening process window can be dominated by or exclusively found at one end of the CD plot. Widening of the process window at higher CDs is generally consistent with decreases in scum and/or microbridge defects.

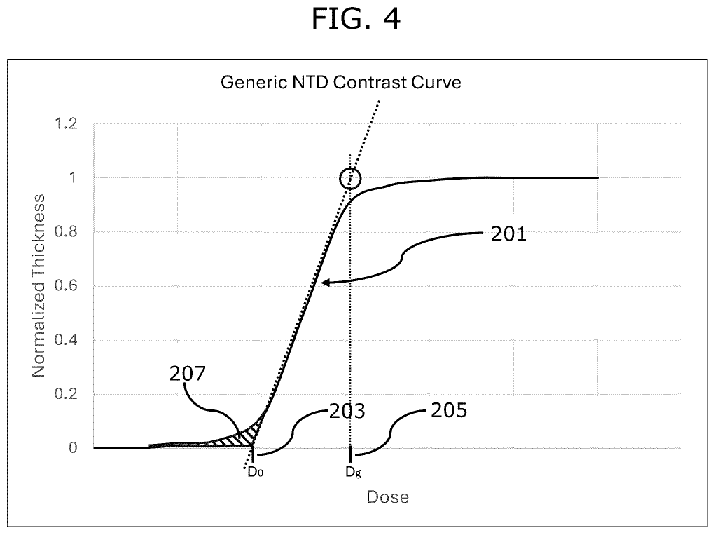

Contrast curves can be particularly useful for evaluating the effectiveness of a developer. A contrast curve is generally prepared by exposing the photoresist film to different doses of energy from a radiation source and developing the wafer to remove material based on the doses delivered. The thickness of the photoresist remaining vs. dose after development can then be plotted to generate a contrast curve. A generic negative-tone contrast curve is shown in FIG. 4. Contrast curve 201 plots the normalized photoresist thickness as a function of exposure dose, wherein for a negative-tone photoresist, the photoresist is substantially removed at doses below critical dose (D₀) 203 and substantially not removed above dose-to-gel (De) 205. As can be seen in FIG. 4, these values are identified from the plots using a tangent line along the largest slope of the curve, with Dₒ identified as the intercept dose at 0 normalized thickness and D_{g} identified as the dose at a normalized thickness of 1. While contrast curves are obtained without patterning of fine features, they provide significant information relating to patterning due to spatial inhomogeneity of irradiation dose along patterns.

For some process conditions, developers, or photoresists, there can be some material that is not completely removed by the developer that is referred to as a “footer”, which may correspond to some material that is partially exposed. The footer region 207 of the contrast curve in FIG. 4 reflects material that is less exposed and mostly soluble in the developer but where some residual material can remain. The residual footer material can be indicative of a process and/or material that can lead to the formation of scum and/or micro-bridging between patterned features, although other process complexities may also contribute. Similarly, a corresponding header region is located near the D_{g} dose that corresponds to exposed material that is not fully gelled, which can develop into a rough feature edge or potentially a line break. Therefore, it is desirable for a developer and/or process to be able to better remove the footer region and/or header region without substantially increasing D₀ or D_{g}. An ideal contrast curve would have a step function shape, which would suggest infinite contrast and removal of the footer region and the header region with a corresponding decrease in remaining residual material following development and less edge roughness.

For negative tone patterning, a developer that is more effective to remove underexposed material may be correspondingly better at removing footer material that can result in defects. The alkylsulfonic acid developers described herein can improve resist patterning by reducing patterned defects such as breaks or microbridges. Breaks, such as line breaks, can occur due to material inhomogeneities in the patterned features that translate to solubility inhomogeneities during development. Breaks in the resist pattern can be improved owing to the strength of the alkylsulfonic acid developers which can remove material that has been exposed to relatively low radiation doses. Higher patterning doses are generally used to render the photoresist material insoluble in the alkylsulfonic acid developers which can lead to a more condensed exposed material that is less susceptible to breaks. Similarly, the strength of the alkylsulfonic acid developers can lead to a reduction in microbridge defects. The alkylsulfonic acid developers can remove more irradiated and/or condensed photoresist material relative to organic developers, and the otherwise insoluble material that would form microbridges between features can be better removed. Taken together, the total defectivity of the patterned resist can be improved.

It can also be desirable for a developer to exhibit continuous etch behavior such that the etch rate for the resist remains non-zero. In other words, longer development times can result in removal of more photoresist material, and this behavior ultimately can result in some removal of sufficiently irradiated (generally around D_{g} or above) material, especially in the header region. A developer that exhibits a continuous etch behavior can be advantageous for reducing patterned defects, such as microbridges, by enabling the developer to remove more material during longer development processes. Termination of the development process involves removal of the developer such as through evaporation of developer, a neutral rinse, for example, with water, rapid rotation of the substrate to mechanically ‘fling’ the developer off of the substrate, or any other appropriate approach. Defects such as microbridges can form between adjacent patterned features and can lead to deleterious effects on integrated circuit and device performance. It is therefore desirable to remove microbridges and other defects by using developers that are able to continuously remove exposed material from the patterned wafer where improved patterning results can be achieved through a careful balance of developer strength, development time, and lithographic processing. The alkylsulfonic acid developer solutions described herein can exhibit a continuous etch behavior wherein longer development times results in increased removal of exposed material. To control the development time for a developer with continuous etch behavior, the development is terminated at a desired point in time, as described below.

As used herein, an alkylsulfonic acid refers to a compound represented by the formula R¹SO³H. Generally, alkylsufonic acids are strong acids. An alkylsulfonic acid composition refers to an alkylsulfonic acid or a combination of two or more different alkylsulfonic acid species. Suitable alkylsulfonic acid species can be described by the formula R¹SO³H where R¹ is a linear, branched, cyclic, or aromatic alkyl group having from 1 to 10 carbons, which can optionally have heteroatom functional groups. For example, suitable alkylsulfonic acid compositions can comprise, for example, methanesulfonic acid, ethanesulfonic acid, propanesulfonic acid, iso-propanesulfonic acid, p-toluene sulfonic acid (tosylic acid), benzenesulfonic acid, or a combination thereof. In some embodiments, R¹ can comprise a fluorinated linear, branched, cyclic, or aromatic alkyl group having from 1 to 10 carbons, wherein at least one H has been replaced by F. A suitable example of a fluorinated alkylsulfonic acid is trifluoromethyl sulfonic acid (triflic acid, CF₃SO₃H), which is a very strong acid and can be considered a superacid. The structure of suitable alkylsulfonic acids can generally be represented by the structure:

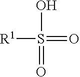

wherein the identity of the group R′ is described above for various embodiments.

The alkylsulfonic acid compositions can be dissolved in any suitable solvent to form an alkylsulfonic developer solution. In some embodiments the alkylsulfonic acid composition comprises a single alkylsulfonic acid species R¹SO₃H while in other embodiments the alkylsulfonic acid composition comprises a combination of two or more suitable alkylsulfonic acid species R¹SO₃H and R²SO₃H, wherein R¹ and R² are different and are independently linear, branched, cyclic, or aromatic alkyl group having from 1 to 10 carbons, optionally fluorinated wherein at least one H has been replaced by F. Suitable sulfonic acids include, for example, methanesulfonic acid, ethanesulfonic acid, propanesulfonic acid, propane-2-sulfonic acid, p-toluene sulfonic acid, benzene sulfonic acid, triflic acid, or a combination thereof. Suitable solvents are those that can dissolve the alkylsulfonic acid composition completely at desired concentrations to form stable solutions. In some embodiments, the solvent can comprise water, and examples are presented herein for developer solutions based on water, although other solvents are also exemplified. As used herein, aqueous developer solutions refer to developer solutions in which water is the predominant solvent. In some embodiments, the solvent can be an aqueous solvent system which in addition to water can comprise additional polar organic co-solvents without substantially altering the aqueous nature of the developer solution. In some embodiments, the aqueous solvent system can comprise at least about 80%, 85%, 90%, or more water by weight of the total solvent system. The remaining portion of the solvent system can comprise any suitable polar organic solvents, for example an alcohol, an ether, an ester, a ketone, or a combination thereof.

While water-based developer solutions have been identified as particularly suitable embodiments, developer solutions based on organic solvents can be desirable for compatibility with lithographic processes and machines. It can be easier to implement development processes when they utilize a similar solvent with respect to historical processing and do not require additional considerations and/or process equipment. In some embodiments, the solvent can comprise either propylene glycol methyl ether acetate (PGMEA), an alcohol, or a combination of alcohols, for example a mixture of 1-pentanol and 1-propanol, as exemplified herein. The mixture of 1-pentanol and 1-propanol can comprise various ratios of the two constituents from about 1% 1-pentanol and the balance 1-propanol to about 99% 1-pentanol and the balance 1-propanol. In other embodiments, the solvent can be a polar organic solvent or a combination of polar organic solvents. Some suitable examples of polar organic solvents are alcohols (e.g., methanol, ethanol, propanol, butanol, pentanol, their isomers, and mixtures thereof), ethers, esters, ketones.

Suitable concentrations of alkylsulfonic acid compositions in the alkylsulfonic developer solution can generally be expressed as molarities (i.e. moles of alkylsulfonic acid composition per total volume of developer solution). Suitable concentrations of alkylsulfonic acid can generally depend on the acidity of the alkylsulfonic acid. Lower concentrations of alkylsulfonic acid can be useful for fluorinated alkylsulfonic acids, such as triflic acid, whereas higher concentrations can be useful for less acidic alkylsulfonic acids. In some embodiments, the alkylsulfonic acid developer solution can comprise from about 0.001 M to about 3.0 M alkylsulfonic acid composition, from about 0.01 M to about 2 M alkylsulfonic acid composition in some embodiments, and from about 0.015 M to about 1.5 M alkylsulfonic acid composition in further embodiments. In some embodiments, the alkylsulfonic acid developer solution can comprise the alkylsulfonic acid composition at a concentration from about 0.05 M to about 0.5 M, while in other embodiments the concentration of alkylsulfonic acid composition can be from about 0.10 M to about 0.30 M, and about 0.15 M in further embodiments. Suitable ranges include ranges with any lower limit specified above combined with any upper limit specified above along with any subranges. A person or ordinary skill in the art will recognize that additional ranges of molarities within the explicit ranges above are contemplated and are within the present disclosure.

Development, as a first development or subsequent development (descum), can generally be accomplished by contacting an organometallic material with an alkylsulfonic acid developer solution. The contacting can be performed through any suitable method known in the art. In some embodiments, the organometallic material can be submerged in the alkylsulfonic acid developer solution. In some embodiments, the development process comprises a puddle development process, as it is commonly referred to in the art, wherein the alkylsulfonic acid developer solution can form a puddle upon the organometallic material. The puddle development process comprises the steps of first dispensing the alkylsulfonic acid developer solution onto the organometallic material, then allowing the dispensed alkylsulfonic acid developer solution puddle to contact the organometallic material for a specified duration, before removing the solution and dissolved material through any appropriate method.

The dispensing can be performed by delivering the liquid developer to the surface of the coated substrate by any approach for dispensing a solution known in the art, for example a nozzle, a dispenser, an applicator, a showerhead, or a sprayer. In some embodiments, the structure for dispensing can comprise multiple nozzles (e.g., a showerhead) capable of dispensing solution simultaneously to enhance coverage uniformity. In some embodiments, the dispenser can be translated across the substrate, progressing from one point of the substrate to another point of the substrate, to form a puddle of liquid developer on the working surface of the substrate. The translation can occur between any two points of the substrate, although it can be preferable to translate the dispenser from one edge of the substrate to the opposing edge of the substrate, or from a center portion of the substrate to an edge of the substrate. In some embodiments, the translating can be performed at a linear speed of from about 10 mm/s to about 100 mm/s, from about 20 mm/s to about 75 mm/s in some embodiments, and from about 30 mm/s to about 50 mm/s in further embodiments. In some embodiments, the liquid developer can be dispensed at a flow rate of from about 0.1 mL/s to about 25 mL/s, from about 0.5 mL/s to about 15 mL/s in some embodiments, and from about 1 mL/s to about 10 mL/s in further embodiments. A suitable volume of developer dispensed can be generally dependent upon the size of the substrate to be developed, such that larger substrates generally require large volumes of liquid developer needed to form a puddle, as well as the wettability of the substrate surface. The dispensing can be performed while the substrate is stationary or while the substrate is mechanically rotated to facilitate thorough coverage across the entire wafer. Structures for dispensing vapor developer compositions is described in published U.S. patent application 2023/0100995 to Cardineau et al. (the '995 application) entitled “High resolution Latent Image Processing, Contrast Enhancement and Thermal Development,” incorporated herein by reference. Structures described in the '995 application can be adapted for the dispensing liquid developers.

Following the puddle formation process, the puddle of liquid developer is allowed to contact the organometallic coating for a specified amount of time known as the development time. During the contacting step, the puddle can either stand and/or rotate slowly without substantially being removed from the working surface of the substrate. Rotating the substrate can be beneficial for realizing improved coverage and more thorough contact between the developer solution and organometallic coating.

The contacting step can be performed for various durations, referred to as the development time. As noted above and demonstrated in the Examples, alkylsulfonic acid developers exhibit continuous etch behavior during development. Thus, the dissolution of photoresist material continues as long as the processing is not terminated. As a result, the development should be purposefully terminated at the end of the desired development period. To achieve reproducible development results, it can be desirable to control the development time with reasonable precision. The selected development time may be influenced by the specific alkylsulfonic acid composition and developer concentration as well as the process details and resist composition. Generally, the development time can be selected to realize desired development results. In some embodiments the development time can be from about 5 seconds to about 10 minutes, in other embodiments from about 7 seconds to about 7 minutes, and in further embodiments the development time can be from about 10 seconds to about 5 minutes. In further embodiments, the development time can be from about 30 seconds to about 90 seconds, and in further embodiments the development time can be no more than about 2 minutes. Relative to a target development time, an actual development time can be within ±5%, in some embodiments ±3%, and in further embodiments ±2% of the target development time. A person of ordinary skill in the art will recognize that additional ranges of development times and development time precision within the explicit ranges above are contemplated and are within the present disclosure.

The developer solution can generally be removed to terminate the contacting step at the end of the development time and remove dissolved material. In some embodiments, the removal of the developer solution can be achieved by rapidly rotating the substrate with organometallic material to remove the developer solution and dissolved material. Suitable rotation speeds of the substrate can generally be expressed in terms of rotations per minute (rpm). In some embodiments, the substrate can be rotated at from about 100 rpm to about 5000 rpm, from about 200 rpm to about 3000 rpm in some embodiments, and from about 300 rpm to about 2000 rpm in further embodiments. A person of ordinary skill in the art will recognize that additional ranges of rpm within the explicit ranges above are contemplated and are within the present disclosure.

In some embodiments, the puddle development process can further comprise a rinse step wherein the patterned coating can be rinsed with water, other inert solvent and/or blown dry with nitrogen (N₂) or other inert gas, for example Ar, or a combination thereof to facilitate removal of the developer solution. When the rinse agent is a liquid, the rinsing can be conducted by dispensing the rinse liquid via the same methods described for dispensing the developer solution. For the rinse step, it can be desirable to dispense the rinse liquid while the substrate is being rotated to enhance uniform coverage via centrifugal force. The flow of inert gas can include flowing the inert gas through a nozzle directed at a non-normal angle towards the working surface of the substrate and can include progressing the flow from a center portion of the substrate to an edge of the substrate. The inert gas flow is generally directed at areas of the substrate where the rinse liquid has finished dispensing. For example, the rinse liquid can initially be dispensed near the center of the substrate and, after the rinse liquid nozzle progresses towards an edge of the substrate, the inert gas flow can be directed along the same path.

Organotin compounds, particularly those based on monoalkyltin trialkoxide (RSn(OR′)₃) and monoalkyltin triamide (RSn(NR′₂)₃) precursor compounds, are particularly useful as precursors for organometallic photoresist compositions for EUV lithography. The use of alkyltin compounds in high performance radiation-based patterning compositions is described, for example, in U.S. Pat. No. 9,310,684 to Meyers et al., entitled “Organometallic Solution Based High Resolution Patterning Compositions,” incorporated herein by reference. Refinements of these organometallic compositions for patterning are described in U.S. Pat. No. 10,642,153 to Meyers et al., entitled “Organometallic Solution Based High Resolution Patterning Compositions and Corresponding Methods,” and U.S. Pat. No. 10,228,618 to Meyers et al. (hereinafter the '618 patent), entitled “Organotin Oxide Hydroxide Patterning Compositions, Precursors, and Patterning,” both of which are incorporated herein by reference. These organotin resist compositions are commercially available from Applicant, Inpria, Inc.

The alkyltin precursor compositions comprise a group ligated to tin that can be hydrolyzed (interchangeably referred to as a hydrolysable ligand) with water or other suitable reagent under appropriate conditions to form monoalkyl tin oxo-hydroxo patterning compositions, which, when fully hydrolyzed, can be represented by the formula RSnO_{(1.5-(x/2))}(OH)ₓ where 0<x≤3. It can be convenient to perform the hydrolysis to form the oxo-hydroxo compositions in situ, such as during deposition and/or following initial coating formation. The coating material generally forms an oxo-hydroxo network with alkyl ligands influencing its solubility properties for the non-irradiated material. While alkyl tin triamides and alkyl tin triacetylides described, for example, in the above-referenced '618 patent, can be used under hydrolyzing conditions for forming radiation sensitive coatings for patterning, it can be desirable to use alkyl tin trialkoxides as part of solution-based film-forming compositions.

Monoalkyl tin precursor compositions can generally be represented by the formula RSnL₃, where R can be an organo group having a radiation-sensitive Sn—C bond and L is a hydrolysable ligand. In some embodiments, R is an alkyl group having a radiation-sensitive Sn—C bond and from about 1 to about 31 carbons atoms, optionally substituted, for example, with a cyano, thio, silyl, ether, keto, ester, or halogenated functional group or a combination thereof, and optionally including unsaturated bonds. For processing to form radiation patternable coatings, L is generally hydrolyzed before or during (e.g., in-situ) deposition to result in a coating comprising an organotin oxo-hydroxo composition on a substrate wherein the Sn—R bonds remain substantially intact. As a result, a radiation patternable coating having radiation-sensitive Sn—R bonds can be realized.

Processing of the organotin precursor compositions to afford organotin oxo-hydroxo coatings generally involves hydrolysis of the RSnL₃ composition(s) to afford the related organotin oxo-hydroxo composition(s). Hydrolysis can be performed prior to the deposition process to yield soluble organotin oxo-hydroxo species (i.e., clusters, oligomeric species, etc.). These soluble organotin oxo-hydroxo species can then be dissolved and/or dispersed into a suitable solvent to form an organotin photoresist solution that can then be used to form radiation-patternable organotin oxo-hydroxo coatings. Alternatively, the organotin precursor compositions can be directly dissolved in a suitable solvent to form a photoresist solution that can then be used to form radiation-patternable organotin oxo-hydroxo coatings. The organotin precursor compositions can also be hydrolysed in-situ with water during the substrate coating process, such as during vapor deposition. Various processing options are described further in the '684 and '618 patents referenced above. Commercial embodiments have been based on in situ hydrolysis of hydrolysable ligands. It is generally believed that hydrolysis begins during the deposition process, and progression of the hydrolysis can take place at various processing stages, which may depend on the specific processing conditions. In any case, the hydrolysis is believed to be completed or substantially completed prior to irradiation.

For organotin photoresist compositions wherein the organotin precursor(s) are dissolved into a solvent for spin-coating, organotin trialkoxides (RSnL₃, L=OR′) can be desirable for use over other RSnL₃ compositions (e.g, organotin triamides, L=NR′₂). Some advantages to organotin trialkoxide compositions are, for example, the production of more benign side-products, e.g., alcohols, that are relatively innocuous compared to the production of gaseous products (e.g., amines) which may cause contamination concerns, environmental health and safety concerns, and/or similar concerns within the wafer track and/or wafer fab. While organotin triamides are known to be useful as precursors in vapor-based deposition methods (as described in the '618 patent), organotin trialkoxides also possess appreciable vapor pressures and low melting points which make them attractive compounds for use in vapor deposition methods to prepare radiation-patternable coatings.

With respect to suitable organotin compositions, suitable embodiments of R can include a linear, branched, (i.e., secondary or tertiary at the metal bonded carbon atom) or cyclic hydrocarbyl group, as well as optional unsaturated and/or aromatic groups. Each R group individually generally has from 1 to 31 carbon atoms with 3 to 31 carbon atoms for the secondary-bonded carbon atom and 4 to 31 carbon atoms for the tertiary-bonded carbon atom embodiments, for example, methyl, ethyl, propyl, butyl, propenyl, butenyl, pentenyl, and isomers thereof. In other embodiments R can include aryl, or alkenyl groups, for example benzyl, allyl, or alkynyl groups. In other embodiments, R may include any group consisting solely of C and H, and containing from 1 to 31 carbon atoms, for example, linear or branched alkyl (ⁱPr, ⁱBu, Me, ⁿBu), cyclo-alkyl (cyclo-propyl, cyclo-butyl, cyclo-pentyl), olefinic (alkenyl, aryl, allylic), or alkynyl groups, or combinations thereof. Suitable heteroatom functional groups can comprise O, S, N, Si, Ge, Sn, Te, halogen atoms, or a combination thereof.

In further embodiments suitable embodiments of R may include hydrocarbyl groups substituted with hetero-atom functional groups such as cyano, thio, silyl, ether, keto, ester, halogenated groups, groups containing Ge, Sn, or Te, or combinations thereof. In the relevant art, organo, hydrocarbyl, and alkyl generally are used interchangeably unless an alternative view follows in context. It has been found that blends of organo groups in the organotin compositions can provide desirable patterning properties taking advantage of desirable features of each group. Precursor blends are exemplified below that are based on Applicant's commercial resist products.

The organotin photoresist precursors can be deposited from solution or vapor-based methods. Vapor-based deposition of organotin photoresists generally involves the introduction the hydrolysable organotin precursors (e.g., RₙSnL₄₋ₙ, where n=1-3) as vapor in a reactor closed from the ambient atmosphere, and these precursors can then be at least partially hydrolyzed as part of the deposition process, i.e., a chemical vapor deposition process. For example, an organotin precursor can be reacted with an oxygen containing precursor, such as H₂O and/or O₂, to result in the formation of an organotin oxide hydroxide coating. Vapor-based deposition of organotin photoresists has described, for example, in the '618 patent. Advantages of vapor deposition methods may include, for example, reduced resist film defect density, improved thickness and compositional uniformity, as well as conformal and side-wall coating of substrate topography.

While vapor-based methods are useful, solution-based methods for formation of organotin photoresist films can also be desirable and can offer other advantages, such as allowing for beneficial additives and allowing for a broader range of blended precursor compositions. For solution deposition, the photoresist precursor solutions with organotin compositions can be used to form radiation-patternable organotin oxo hydroxo coatings can be formed using any suitable method known in the art. Spin coating can be particularly desirable for forming coatings using the photoresist precursor solutions. In a typical spin coating process, a volume of a photoresist solution is introduced onto the surface of a substrate, and the substrate is rotated at high speeds to drive rapid evaporation and hydrolysis processes to enable the formation of a radiation patternable coating. In some embodiments, the substrate can be spun at rates (i.e., spin speeds) from about 500 rpm to about 10,000 rpm, in further embodiments from about 1000 rpm to about 7500 rpm, and in additional embodiments from about 2000 rpm to about 6000 rpm. The spin speed can be adjusted to obtain a desired coating thickness. The spin coating can be performed from about 5 seconds to about 5 minutes and in further embodiments from about 15 seconds to about 2 minutes. An initial low speed spin, e.g., at 50 rpm to 250 rpm, can be used to perform an initial bulk spreading of the composition across the substrate. A back side rinse, edge bead removal step, or the like can be performed with water or other suitable solvent to remove any edge bead. A person or ordinary skill in the art will recognize that additional ranges of spin coating parameters within the explicit ranges above are contemplated and are within the present disclosure.

A substrate generally presents a surface onto which the coating material can be deposited, and the substrate may comprise a plurality of layers in which the surface relates to an upper most layer. The substrate surface can be treated to prepare the surface for adhesion of the coating material. Prior to preparation of the surface, the surface can be cleaned and/or smoothed as appropriate. Suitable substrate surfaces can comprise any reasonable material. Some substrates of interest include, for example, silicon wafers, silica substrates, other inorganic materials, polymer substrates, such as organic polymers, composites thereof and combinations thereof across a surface and/or in layers of the substrate. In some embodiments, the substrate can comprise a patterned structure such as described by Stowers et al. in U.S. Pat. No. 10,649,328, entitled “Pre-Patterned Lithography Templates, Process Based on Radiation Patterning Using The Templates And Processes To Form The Templates”, incorporated herein by reference.

The thickness of the coating generally can be a function of the precursor solution concentration, viscosity and the spin speed for spin coating. For other coating processes, the thickness can generally also be adjusted through the selection of the coating parameters. As noted above, many precursors can be deposited by vapor deposition, and flow rates, times, pressures and other parameters can be adjusted to yield a desired coating. In some embodiments, it can be desirable to use a thin coating to facilitate formation of small and highly resolved features in the subsequent patterning process. For example, the coating materials after drying can have an average thickness of no more than about 250 nanometers (nm), in additional embodiments from about 1 nm to about 50 nm, in other embodiments from about 2 nm to about 40 nm and in further embodiments from about 3 nm to about 25 nm. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the film. In general, the coatings are relatively uniform to facilitate processing. In some embodiments, such as high uniformity coatings on reasonably sized substrates, the evaluation of coating uniformity or flatness may be evaluated with, for example, a 1-centimeter edge exclusion, i.e., the coating uniformity is not evaluated for portions of the coating within 1 centimeter of the edge, although other suitable edge exclusions can be selected.

While heating may not be needed for successful application of the deposition process, it can be desirable to heat the coated substrate to densify the coating material, to speed the processing, to increase the reproducibility of the process, and/or to facilitate vaporization of the hydrolysis by-products, such as alcohols and/or amines. In embodiments in which heating of the coated substrate is performed prior to irradiation (post application bake), the coated substrate can be heated to temperatures from about 45° C. to about 250° C., in further embodiments from about 55° C. to about 225° C., and in additional embodiments from about 65° C. to about 200° C. The heating can generally be performed for at least about 0.1 minute, in further embodiments for about 0.5 minutes to about 30 minutes, and in additional embodiments from about 0.75 minutes to about 10 minutes. The heating may be performed, for example, in air, vacuum, a controlled gas composition or an inert gas ambient, such as Ar or N₂. A controlled rest period can be introduced before and/or after the heating, and the heating process can also be divided into different steps, which may or may not have different conditions. In some embodiments, such a rest step can be for a selected period of time from about 30 seconds to about 1 hour. A person of ordinary skill in the art will recognize that additional ranges of heating temperatures and times within the explicit ranges above are contemplated and are within the present disclosure.

In general, while suitable radiation sources are those that generally provide for wavelengths that effectively absorb in the photoresist, typical radiation sources generally correspond to commercial lithography applications. For example, wavelengths most relevant to lithography include commercial EUV exposure tools (such as those fabricated by ASML) which operate at a wavelength of 13.5 nm and commercial UV exposure tools which generally operate at a wavelength of 193 nm for ArF excimer laser sources or 248 nm for KrF excimer laser sources. A person of ordinary skill in the art will understand that other absorbative wavelengths are contemplated and within the scope of the disclosure. The international standard for optics and photonics is ISO 20473: 2007 (E), incorporated herein by reference. This standard has the broad range of UV wavelengths from 1 nm to 380 nm, with the EUV range from 1 nm to 100 nm.

The amount of electromagnetic radiation can be characterized by a fluence or dose which is obtained by the integrated radiative flux over the exposure time. For embodiments in which EUV radiation is used, suitable radiation doses can be from about 1 mJ/cm² to about 150 mJ/cm², in further embodiments from about 2 mJ/cm² to about 100 mJ/cm² and in further embodiments from about 3 mJ/cm² to about 50 mJ/cm². A person of ordinary skill in the art will recognize that additional ranges of radiation fluences within the explicit ranges above are contemplated and are within the present disclosure.

Following exposure to radiation and the formation of a latent image, a subsequent postexposure bake (PEB) step is typically performed. In some embodiments, the PEB can be performed at temperatures from about 45° C. to about 250° C., in additional embodiments from about 50° C. to about 220° C., in some embodiments from about 80° C. to about 200° C. and in further embodiments from about 90° C. to about 185° C. The post exposure heating can generally be performed for at least about 0.1 minute, in further embodiments from about 0.5 minutes to about 30 minutes and in additional embodiments from about 0.75 minutes to about 10 minutes. The heating may be performed in air, vacuum, a controlled gas atmosphere, or an inert gas ambient, such as Ar or N₂, and heating steps can be broken into separate heating steps with different gaseous environments. One or more controlled rest times can be introduced before, after or between heating steps, and the pressure and gas atmosphere can be controlled during a rest step. A person of ordinary skill in the art will recognize that additional ranges of PEB temperatures and times within the explicit ranges above are contemplated and are within the present disclosure. The PEB can be designed to further consolidate the exposed regions without decomposing the un-exposed regions into a metal oxide.

In some embodiments, a second postexposure bake (PEB) step can be performed after a first, initial PEB step, for example, to reduce the radiation dose necessary to achieve desired patterning features. With regard to commercial integrated circuit production, this can be desirable to reduce the cost and time associated with higher radiation doses, thereby potentially improving the economic feasibility and throughput of the process. The temperature of the second PEB can be the same or different from the temperature of the first PEB, although the temperature and duration of the second PEB step can be selected according to the same criteria as the first PEB step. Generally, it can be desirable to rest the coated substrate at ambient temperature during a rest step after the first PEB step and before the second PEB step. In some embodiments, the rest step can be from about 30 seconds to about 30 minutes while in other embodiments the rest step is from about 1 minute to about 15 minutes, and from about 2 minutes to about 5 minutes in further embodiments. The temperature of the rest step is generally conducted at the ambient temperature of the fabrication facility (fab), which can vary and is generally between about 15° C. and about 30° C. in some embodiments, and between about 20° C. and 25° C. in other embodiments. Following the rest step, the coated substrate can be subjected to a second PEB, which may be at the same or different conditions. The effective use of rest steps in processing is described further in copending U.S. patent application Ser. No. 19/065,726 to De Schepper et al., entitled “Controlled Environment Processing, Rest Steps and Baking Processes for Metal Oxide-Based Resist Patterning,” incorporated herein by reference. A person of ordinary skill in the art will recognize that additional ranges of rest step temperatures and times within the explicit ranges above are contemplated and are within the present disclosure. Following at least one or more PEB steps the coated substrate can be developed by contacting the coated substrate with an alkylsulfonic acid developer solution, as described herein.

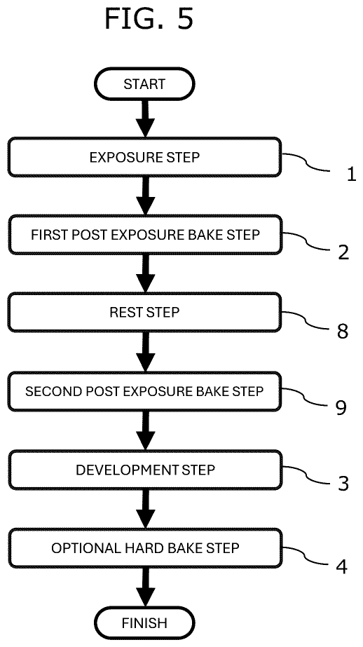

A method of patterning a radiation patternable organometallic coated substrate comprising a controlled rest step and two post exposure bake steps is depicted in a flow diagram of FIG. 5. A radiation pattern is projected on the coated substrate in exposure step 1 to create a latent image comprising exposed and unexposed regions. The coated substrate is baked in a first post exposure bake step 2, then rested in rest step 8 before being baked in a second post exposure bake step 9. The coated substrate is then contacted with an alkylsulfonic acid developer solution in development step 3 to preferentially remove unexposed regions while substantially retaining exposed regions, and optionally undergoes hard bake step 4. As exemplified herein, the addition of a rest step and subsequent second post exposure bake step can reduce the radiation dose required to render the irradiated organometallic material insoluble in the alkylsulfonic acid developer solution without significant losses in pattern quality. Decreases in radiation dose can translate into increased throughput during integrated circuit production.

Performance of a first development step or subsequent development-descumming step is described further above. In some embodiments, following development with an alkylsulfonic acid developer, a descum step can be conducted with an alternative liquid, if desired, to further remove undesired material from the pattern, and such methods have been described in published U.S. Patent Application No. 2020/0124970 to Kocsis et al., entitled “Patterned Organometallic Photoresists and Methods of Patterning,” incorporated herein by reference. With respect to performance of a descumming step with alkylsulfonic acid, this generally implies the performance of a prior development step. While the initial development step may also be performed with alkylsulfonic acid, the initial development step can be performed with a different liquid developer or using a dry development process. Various liquid developers can be suitable for negative tone development with the organometallic resist materials, such as an organic solvent suitable for resist delivery. Applicant has developed improved liquid developers using liquid blends. See the '627 application cited above.

It has also been discovered that liquid free development, also referred to as dry development, can be employed with organotin materials. Dry development can include, for example, selective removal of the irradiated or non-irradiated regions of the photoresist by exposing the material to an appropriate plasma or appropriate flowing gas. Dry development of organotin resists has been described in PCT Publication No. 2020/132281A1 by Volosskiy et al., entitled “Dry Development of Resists”, and in published U.S. Patent Application 2023/0100995 by Cardineau et al., entitled “Method for Enhancing Development Contrast and Apparatuses for Processing Substrate”, both of which are incorporated herein by reference. In such dry development processes, development can be achieved by exposing the coated, irradiated substrate to a plasma or a thermal process while flowing a gas comprising a small molecule reactant that facilitates removal of irradiated or non-irradiated regions. Effective “dry” methods for developing these organotin resists have been developed, see U.S. Pat. No. 11,079,682 to Han et al., entitled “Method for Extreme Ultraviolet (EUV) Resist Patterning Development,” incorporated herein by reference. Plasma reactors for dry development are available from Tokyo Electron Limited.

After an initial development step and prior to a descum step, another optional bake step can be performed between the development step and the descum step and can be referred to as a post development bake (PDB). This optional intermediate bake step can be performed at temperatures from about 45° C. to about 250° C., in additional embodiments from about 50° C. to about 220° C., in some embodiments from about 80° C. to about 200° C. and in further embodiments from about 90° C. to about 185° C. The post development bake step can generally be performed for at least about 0.1 minute, in further embodiments from about 0.5 minutes to about 30 minutes and in additional embodiments from about 0.75 minutes to about 10 minutes. The heating may be performed in air, vacuum, a controlled gas atmosphere, or an inert gas ambient, such as Ar or N₂, and heating steps can be broken into separate heating steps with different gaseous environments. A person of ordinary skill in the art will recognize that additional ranges of times and temperatures within the explicit ranges above are contemplated and are within the present disclosure. The general idea of a double bake double development process is also described in published U.S. patent application 2024/0085785 to Kasahare et al., entitled “Additives for Metal Oxide Photoresists, Positive Tone Development With Additives, and Double Bake Double Develop Processing,” incorporated herein by reference.

Following development and any optional descumming step, it may be desirable to perform a hard bake, on the newly formed resist pattern to drive off remaining developer solution and to improve the fidelity of the patterned lines. In general, the hard bake conditions can be similar to the PEB step. In some embodiments, the hard bake can be performed at temperatures of at least about 45° C., in some embodiments from about 45° C. to about 400° C., in additional embodiments from about 50° C. to about 300° C. and in further embodiments from about 60° C. to about 250° C. The hard bake can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of hard bake temperatures and times within the explicit ranges are contemplated and are within the present disclosure.

Wafer throughput is a substantially limiting factor for implementation of EUV lithography in high-volume semiconductor manufacturing, and it is directly related to the dose required to pattern a given feature. With patterning efforts to date, a negative correlation between the imaging dose required to print a target feature, and feature size uniformity (such as LWR) is commonly observed for EUV photoresists at feature sizes and pitches <50 nm, thereby limiting final device operability and wafer yields. Efforts continue to lower dose to achieve target features, and improved development offers the possibility to make some advances.

Patterning capability can be expressed in terms of the dose-to-gel value. Imaging dose requirements can be evaluated by forming an array of exposed pads along a film of resist on a wafer or the like, in which the exposure time is stepped from pad to pad to change the dosing of the exposure. The film can then be developed, and the thickness of the remaining resist can be evaluated for all of the pads, for example, using spectroscopic ellipsometry. The measured thicknesses can be normalized to the maximum measured resist thickness and plotted versus the logarithm of exposure dose to form characteristic curves. The maximum slope of the normalized thickness vs log dose curve is defined as the photoresist contrast (Y) and the dose value at which a tangent line drawn through this point equals 1 is defined as the photoresist dose-to-gel, (Dg). D₀ is defined as the point where the tangent line crosses the zero thickness point and roughly corresponds to the onset dose for initial increase in film thickness for a negative-tone resist. In this way common parameters used for photoresist characterization may be approximated following Mack, C. (Fundamental Principles of Optical Lithography, John Wiley & Sons, Chichester, U.K; pp 271-272, 2007, incorporated herein by reference.) Larger values of contrast correspond to a steeper tangent line on the contrast curve. As noted above, a step function would correspond with an idealized contrast curve, and a larger contrast value corresponds with a better approximation to the ideal, although the header and footer regions may also be independently significant.

A patterned structure can be evaluated using combinations of metrology software and automated imaging equipment and scanning electron microscope imagers are generally used. For example, specific commercial CD-SEM instruments can measure critical line dimensions (line widths) and can also evaluate defects, such as microbridging. In some embodiments, the patterning with improved development based on resist engineering described herein can result in an increase in critical dimension using the equivalent development, coating formation and irradiation. Viewed another way, the concept of critical dimension can be expressed as a dose-to-size value, which is the radiation doze used to obtain a specific feature size. So an increase in critical dimension corresponds with a decrease in the dose-to-size value, which is consistent with the ability to use a lower dose to obtain a certain patterning objective.

One approach to generating and analyzing a contrast curve—previously utilized by applicant in the '618 patent—is outlined as follows. An array of circular pads ˜500 μm in diameter were projected on the wafer using EUV light (Lawrence Berkeley National Laboratory Micro Exposure Tool, MET). Pad exposure times were modulated to deliver an increasing EUV dose (7% exponential step) to each pad. Resist and substrate were then subjected to a post-exposure bake (PEB) on a hotplate for 2 min at 160° C. The exposed films were dipped in 2-heptanone for 15 seconds and rinsed an additional 15 seconds with 2-heptanone to form a negative tone image, i.e., unexposed portions of the coating were removed. Residual resist thicknesses of the exposed pads were measured using a J. A. Woollam M-2000 Spectroscopic Ellipsometer. The measured thicknesses were normalized to the maximum measured resist thickness and plotted versus the logarithm of exposure dose to form characteristic curves for each resist at a series of PEB temperatures. The maximum slope of the normalized thickness vs log dose curve is defined as the photoresist contrast (γ), the dose value at which a tangent line drawn through this point equals 1 is defined as the photoresist dose-to-gel, (Dg), the dose value at which the tangent line intersects the zero dose value is defined as D₀. In this way common parameters used for photoresist characterization may be approximated following Mack, C. Fundamental Principles of Optical Lithography, John Wiley & Sons, Chichester, U.K; pp 271-272, 2007, incorporated herein by reference. The examples in this application utilize a similar variation of this approach that incorporates the same underlying principles with baking steps and development performed as described below. Variations of this approach can be used generally for comparable analyses. Ultimately, the goal is to form small features with a low defect rate. A large contrast value generally is desirable, but results herein also suggest that the size of header and footer regions resulting from curvature near the Dg and D₀ values also influence defect rate and line width roughness.

### EXAMPLES

### Example 1: Development and Processing of an Organotin Photoresist with Alkylsulfonic Acid

This example demonstrates the utility of an aqueous alkylsulfonic acid solution as negative-tone developer solution for an organometallic photoresist.

Photoresist films of approximately 22 nm thickness were deposited by spin coating an organotin photoresist blend having an 80:20 molar ratio of tert-butyltin tris(tert-amyloxide) and methyltin tris(tert-amyloxide) onto four silicon wafers A, B, C, and D. The Si wafers were previously coated with about a 60 nm thick bottom anti-reflection coating (DUV46M-306, Brewer Science) which was deposited via spin coating and baked at 200° C. for 60 s to cure. Following coating of the prepared Si wafers with the organotin photoresist, the wafers were subjected to a post-application bake (PAB) at 100° C. for 60 s and then exposed to UV radiation (254 nm wavelength) to produce a contrast array, e.g., an array of pads across each wafer, each pad having been exposed to a different dose of radiation.

Following UV exposure, all four of the wafers were subjected to a first post-exposure bake (PEB) at either 180° C. or 200° C. for 60 s (PEB1). Following an approximately 1-minute-long rest period at room temperature, samples C and D were subsequently subjected to a second PEB (PEB2) at either 180° C. or 200° C. for 60 s. Following completion of the two PEB steps, all four samples were developed for 30 seconds by submerging in an aqueous 0.05 M methane sulfonic acid (MSA) solution. Development was terminated after the selected development time by rinsing the wafer with water to remove the developer and subsequently blowing the wafer dry with N₂. All four of the samples were then hard baked at 250° C. for 60 s (HB). The processing conditions of the organotin photoresist-coated wafers are summarized in Table 1.

TABLE 1

| | PAB | PEB1 | PEB2 | | HB |
|---|---|---|---|---|---|
| | Temp | Temp | Temp | Developer | Temp |
| Sample | (° C.) | (° C.) | (° C.) | Solution | (° C.) |
| A | 100 | 180 | N/A | 0.05M MSA (aq) | 250 |
| B | 100 | 200 | N/A | 0.05M MSA (aq) | 250 |
| C | 100 | 180 | 180 | 0.05M MSA (aq) | 250 |
| D | 100 | 180 | 200 | 0.05M MSA (aq) | 250 |

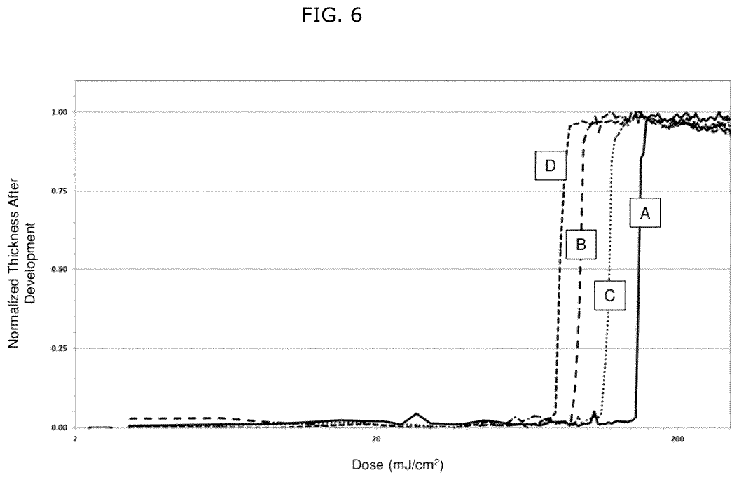

Contrast curves were then generated by measuring the remaining thickness of each pad via ellipsometry and plotting the normalized thickness vs. dose to produce the plots shown in FIG. 6. The normalized thickness was calculated by dividing the measured remaining thickness by the maximum thickness measured for each curve (e.g., maximum normalized thickness=1). A normalized thickness of 1.0 indicates little to no irradiated material was removed during development whereas a normalized thickness of 0 indicates all or almost all of the material was removed during development.

As shown in FIG. 6, high contrast negative-tone behavior was observed with the 0.05 M MSA developer at all of the processing conditions tested. The high contrast negative-tone behavior for Samples A-D is demonstrated by the sharp transition (meaning over a relatively small range of doses) from an effectively zero thickness to a normalized thickness of about 1. For each sample, the contrast curve shows a small footer region area. Sample A, processed with a 180° C. PEB, required a higher dose to induce contrast (i.e. a higher dose-to-gel (D_{g})) than Sample B, processed with a 200° C. PEB. This lower dose-to-gel value for Sample B is consistent with higher PEB temperatures driving irradiated organometallic compositions toward being more condensed and less soluble. For Samples C and D which were processed with a first PEB step (PEB1) equivalent to the PEB for sample A, a intermediate 60 seconds rest step, and a second PEB step (PEB2), the dose-to-gel is also reduced relative to the single 180° C. PEB performed on Sample A. For example, Sample C, which received a first and a second PEB at 180° C. intermediated with a 60 seconds rest step, and Sample D, which received a first PEB at 180° C., an intermediate 60 seconds rest step, and then a second PEB at 200° C., generated contrast at lower doses than Sample A, which received one PEB at 180° C. Similarly, Sample D, which received a first PEB at 180° C. for 60 s and a second PEB at 200° C. for 60 s, generated contrast at lower doses than Sample B which received one PEB at 200° C. for 60 s. This suggests that a second PEB step following a first PEB step and 60-second rest step can reduce the dose-to-gel of the organometallic photoresist material when methane alkylsulfonic acid comprises the developer solution.

Comparative samples processed with only water as the developer showed no removal of photoresist material. The contrast curves generated for these samples do not exhibit a high contrast negative-tone behavior. (Data is not shown.)

These results demonstrate the effectiveness of an aqueous alkylsulfonic acid developer solution for use as a high-contrast negative-tone developer for organometallic photoresists. The results further demonstrate the use of higher temperature baking and/or multiple bake processes (i.e., PEBs) after exposure can reduce the dose-to-gel of the photoresist without significant loss of contrast or solubility.

### Example 2: Wet Descum of Patterned Organotin Photoresist with Aqueous Methanesulfonic Acid Solution

This example demonstrates the utility of using an aqueous alkylsulfonic acid developer solution in a multi-step development process of an organometallic photoresist.

Silicon wafers were prepared for coating with the organometallic photoresist as described in Example 1. Thereafter, photoresist films of approximately 22 nm thickness were deposited by spin coating an organotin photoresist blend having an 80:20 molar ratio of tert-butyltin trialkoxide and methyltin trialkoxide onto the prepared silicon wafers. Following coating of the prepared Si wafers, the wafers subjected to a post-apply bake (PAB) at 100° C. for 60 s and then exposed to UV radiation (254 nm wavelength) to produce a contrast array. The organotin photoresist-coated wafers were processed as summarized in Table 2.

TABLE 2

| | PAB | PEB | | PDB | | HB |
|---|---|---|---|---|---|---|
| | Temp | Temp | | Temp | | Temp |
| Sample | (° C.) | (° C.) | DEV1 | (° C.) | DEV2 | (° C.) |
| RC1 | 100 | 180 | 2-hep | 180 | 0.05M | 250 |
| | | | | | MSA | |
| | | | | | (aq) | |
| RC2 | 100 | 180 | 2-hep | 200 | 0.05M | 250 |
| | | | | | MSA | |
| | | | | | (aq) | |
| RCE | 100 | 180 | 2-hep | N/A | N/A | 250 |

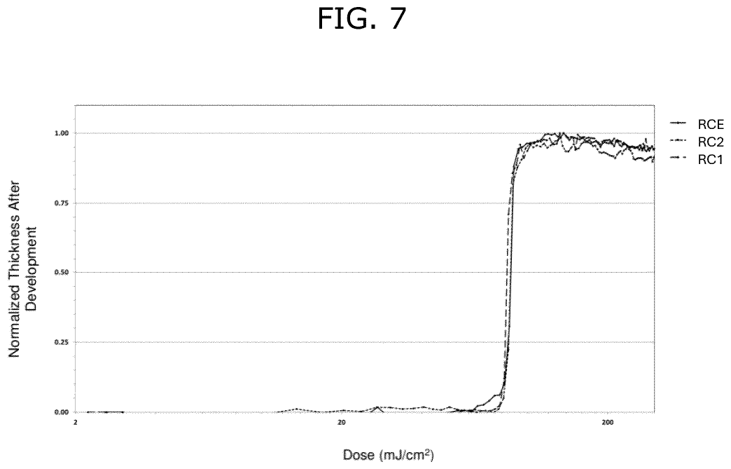

Referring to Table 2, following UV exposure, the wafers were subjected to a post exposure bake step (PEB) at 180° C. for 60 s. Each wafer was then submerged in 2-heptanone (2-hep) in a negative-tone development process. This first development step (DEV1) was intended to remove the unexposed and lightly exposed photoresist. The wafers were then removed from the developer and blown dry with N₂. Following DEV1, Sample RC1 was subjected to a post development bake (PDB) at 180° C. for 60 s, then submerged into an aqueous solution of 0.05 M methane sulfonic acid for 30 s in a second development step (DEV2), rinsed with H₂O, and then blown dry with N₂. Sample RC2 was subjected to a post development bake PDB at 200° C. for 60 s, then submerged into an aqueous solution of 0.05 M methane sulfonic acid for 30 s in a second development step (DEV2), rinsed with H₂O, and then blown dry with N₂. For comparison, wafer RCE did not receive a post development bake step (PDB) or a second development with methane sulfonic acid. All wafers received a final hard bake (HB) of 250° C. for 60 s. Contrast curves were then generated by measuring the remaining thickness of each pad via ellipsometry and plotting the normalized thickness vs. dose to produce the plots shown in FIG. 7.

Referring to FIG. 7, for Samples RC1 and RC2, which received a post development bake (PDB) and a second development with 0.05 M methane sulfonic acid (which can be alternatively termed a “wet descum”), the footer region is noticeably reduced from that of Sample RCE and the contrast seems slightly improved for the RC1 sample. As the dose approaches D₀ (see FIG. 2), the material becomes less and less soluble until the exposed material can no longer be removed by the developer. For development in only 2-heptanone (Sample RCE), there is some material (“footer”) that remains on the substrate at doses below D₀. The results in FIG. 7 show that after forming an initial pattern with 2-heptanone developer, the methane sulfonic acid developer/wet descum can remove this footer material from the patterns. The results suggest that a second development/wet descum with an aqueous sulfonic acid solution after a first development in an organic solvent can result in reduced pattern defectivity via, for example, by enabling removal of lightly exposed material in nominally “dark” areas between patterned features and/or removal of extraneous material, such as microbridges or scumming, which can survive in nominal “dark” areas of the exposed pattern. The results further show that performing a second development/wet descum with methane sulfonic acid does not significantly affect the D_{g} or D₀ values of the photoresist relative to performing a single development with 2-heptanone.

This example demonstrates that a second development/wet descum with methane sulfonic acid can effectively remove unwanted footer region material, such as lightly exposed material, that remained after the initial development step. This example shows that an aqueous alkylsulfonic acid solution can be effective at removing material associated with patterning defects while retaining the desired patterned material as well as high contrast and dose sensitivity.

### Example 3: Defect Window Improvements

This example demonstrates that defect windows can be improved by developing an EUV radiation patterned organometallic photoresist with an aqueous alkylsulfonic acid solution versus a PGMEA/acetic acid solution.

Photoresist films of approximately 24 nm thickness, as confirmed by ellipsometry, were deposited by spin coating an organotin photoresist blend having an 80:20 molar ratio of tert-butyltin tris(tert-amyloxide) and methyltin tris(tert-amyloxide), respectively onto silicon wafers that were previously coated with approximately 10 nm spin-on-glass (SOG). After deposition, the wafers were subjected to a post-apply bake at 100° C. for 60 s. The coated wafers were then patterned with different doses of EUV radiation on an ASML NXE3400 exposure tool to create an array of line/space patterns having a target critical dimension (CD) of 14 nm on a 28 nm pitch. Different spots on the array corresponded to different doses, and the evaluated critical dimension determined was a function of the dose. The wafers were then subjected to a post-exposure bake (PEB) at 180° C. for 60 s. Following the PEB, the wafers were then developed using either an aqueous solution of 0.15 M methanesulfonic acid (MSA) or a solution of 5 wt. % acetic acid in PGMEA (AA). After development, the wafers were subjected to a final hard bake (HB) at 250° C. for 60 s.

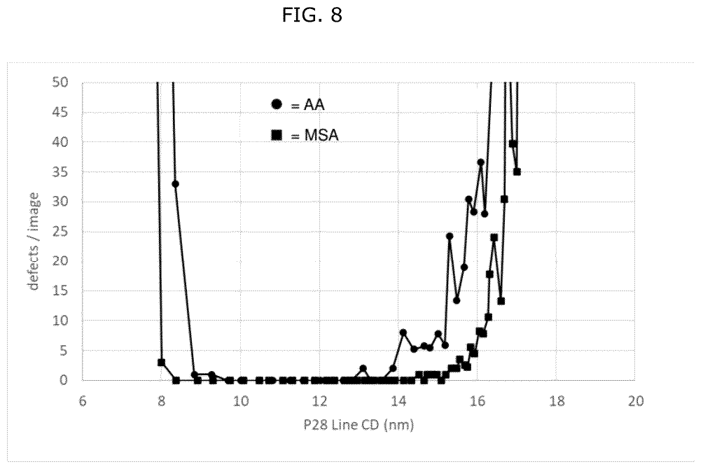

Images of each field were then collected for each wafer sample using a Hitachi CDSEM tool and the images for the target 14p28 patterns were analyzed using a metrology software package from Stochalis to quantify the number of defects at each printed CD. FIG. 8 shows the number of defects vs. CD (dose) for each developer. For the wafer samples developed with the alkylsulfonic acid developer (MSA), the range of CDs in which the number of defects/image is below about 5 is larger than for the wafer samples developed with the acetic acid developer (AA). Advantages can also be described in terms of line width roughness, (LWR): (AA) LWR=2.90 nm at a CD=14.02 nm; (MSA) LWR=2.57 nm at a CD=14.01 nm, although the MSA sample had a higher EUV dose to achieve this critical dimension.

This example shows that a developer solution comprising an alkylsulfonic acid composition can enable EUV patterning of an organometallic photoresist with an improved (larger) defect window at both ends of the CD plot as compared to an acetic acid developer in an organic solvent.

### Example 4: Continuous Etch Behavior with Alkylsulfonic Acid Developer

This example demonstrates the use of an aqueous alkylsulfonic acid solution as a developer having a non-zero minimum development rate (“continuous etch behavior”).

Photoresist films of approximately 24 nm thickness were deposited by spin coating an organotin photoresist blend having an 80:20 molar ratio of tert-butyltin tris(pentan-3-yloxy) and methyltin tris(tert-amyloxide), respectively onto silicon wafers that were previously coated with approximately 10 nm spin-on-glass (SOG). After deposition, the wafers were subjected to a post-apply bake at 100° C. for 60 s. Contrast curves were then generated by exposing the coated wafers to different doses of EUV radiation on an ASML NXE3400 exposure tool. The wafers were then subjected to a PEB of 180° C. for 60 s. Following the PEB, the wafers were then developed with an aqueous solution of 0.15 M methanesulfonic acid. Development was conducted by dispensing the developer solution onto the wafer, allowing the solution to contact the wafer for about 15 s, 30 s, or 90 s, and then rapidly rotating the wafer to remove the solution. Then, each wafer was subjected to a hard bake at 250° C. for 60 s.

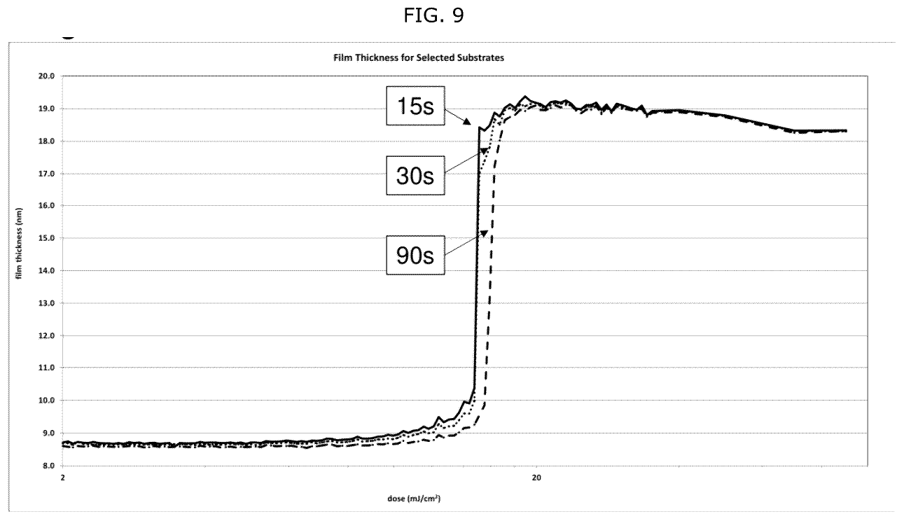

After the hard bake, the thickness of each pad was measured, and the film thickness results were plotted vs. dose to create the contrast curves shown in FIG. 9. As shown in FIG. 9, increasing development time resulted in less footer and header area and slightly higher D₀ and D_{g} values. Notably, the continuous dissolving rate behavior did not result in the significant removal of additional fully irradiated (well above D_{g}) material as development time increased up to 90 seconds. This can be visually determined from the contrast curves, wherein the thickness plateaued to the same value for all three development times. This suggests that the continuous etch rate behavior does not appreciably impact fully irradiated material, which is beneficial for achieving consistent, repeatable results amidst minor variations in processing parameters. These results are indicative of the alkylsulfonic acid developer showing a continuous etch rate behavior without appreciable dissolution of fully irradiated material.

This example shows that an alkylsulfonic acid-based developer is capable of removing more irradiated, condensed photoresist material as development time is increased. This result suggests that alkylsulfonic acid-based developers can enable lower patterned defectivity, such as microbridges, by being able to remove otherwise insoluble material.

### Example 5: Development of Line Space Patterns with Alkylsulfonic Acid Developer Solutions with Aqueous or Nonaqueous Solvents

This example demonstrates the effective development of line space patterns using developer solutions comprising an alkylsulfonic acid composition and a polar organic solvent or water.

Photoresist films of approximately 22 nm to approximately 24 nm thickness, as confirmed by ellipsometry, were deposited by spin coating an organotin photoresist blend having an 80:20 molar ratio of tert-butyltin tris(tert-amyloxide) and methyltin tris(tert-amyloxide), respectively onto silicon wafers that were previously coated with approximately 10 nm spin-on-glass (SOG). After deposition, the wafers were subjected to a post-apply bake (PAB) at 100° C. for 60 s. The coated wafers were then patterned with different doses of 13.5 nm EUV radiation on an ASML NXE3400 exposure tool to create an array of line/space patterns having a target critical dimension (CD) of 14 nm on a 28 nm pitch (14p28). Different locations on the array were subjected to different doses corresponding to different measured values of critical dimension. The wafers were then subjected to a post-exposure bake (PEB) at 180° C. or 190° C. for 60 s. Following the PEB, the wafers were developed by dispensing the developer solution onto the wafer and allowing it to contact the wafer for about 30 seconds before rapidly rotating the wafer to remove the solution. Development was conducted using one of ten methanesulfonic acid (MSA) based developer solution compositions presented in Table 3. The wafers were then subjected to a hard bake for 60 seconds at 250° C.

TABLE 3

| Developer | | Alkylsulfonic Acid |
|---|---|---|
| Solution | Solvent | Composition |
| DA | PGMEA | MSA (0.15M) |
| DB | PGMEA | MSA (0.87M) |
| DC | 62 wt % 1-pentanol, | MSA (0.05M) |
| | 38 wt % 1-propanol | |
| DD | 62 wt % 1-pentanol, | MSA (0.10M) |
| | 38 wt % 1-propanol | |
| DE | 62 wt % 1-pentanol, | MSA (0.15M) |
| | 38 wt % 1-propanol | |
| DF | H₂O | MSA (0.05M) |
| DG | H₂O | MSA (0.10M) |
| DH | H₂O | MSA (0.30M) |
| DI | H₂O | MSA (0.50M) |
| DJ | H₂O | MSA (1.0M) |

Images of each field were then collected for each wafer sample using a Hitachi CD-SEM tool and the images for the target 14p28 patterns were analyzed using a metrology software package from Stochalis to determine the CD closest to the target size of 14 nm and the corresponding dose-to-size and line width roughness. These values are presented in Table 4. For PGMEA (DA and DB), 1-pentaol/1-propanol (DC, DD, and DE), and water (DF, DG, DH, DI and DJ) based developer solutions, an increase in the concentration of methane sulfonic acid in the developer solution either increased or did not significantly (within 0.1 nm) affect both the line width roughness (LWR) and dose-to-size required to achieve 14p28 line space patterns for comparable PEB temperatures. This suggests that lower concentrations of the alkylsulfonic acid composition in the developer solution can be sufficient or even preferable. Coated wafers that were developed with water based solutions exhibited lower line width roughness than the wafers developed with polar organic solvent based solutions. It was noted that CD-SEM images of the coated wafers developed with polar organic solvent based solutions (PGMEA and 1-pentanol/1-propanol) exhibited visible line wiggling and/or swelling, whereas coated wafers developed with water based solutions did not. This correlates with the higher LWR observed for the polar solvent based developer solutions in comparison to the water based developer solutions, as the wiggling and/or swelling can obscure line space patterns to an extent.

TABLE 4

| | PEB | | | |
|---|---|---|---|---|
| Developer | Temp | CD | Dose-to-Size | LWR |
| Solution | (° C.) | (nm) | (mJ/cm²) | (nm) |
| DA | 180 | 14.14 | 43.75 | 5.76 |
| DB | 180 | 13.96 | 63.00 | 6.00 |
| DC | 180 | 14.26 | 49.25 | 5.08 |
| | 190 | 14.36 | 35.00 | 5.57 |
| DD | 180 | 13.85 | 53.75 | 5.92 |
| | 190 | 14.40 | 42.50 | 6.74 |
| DE | 180 | 14.04 | 60.50 | 6.38 |
| | 190 | 13.95 | 45.50 | 6.76 |
| DF | 180 | 14.13 | 46.25 | 3.29 |
| DG | 180 | 14.02 | 46.25 | 3.27 |
| DH | 200 | 14.03 | 32.75 | 3.66 |
| DI | 200 | 14.18 | 34.50 | 3.77 |
| DJ | 200 | 13.99 | 38.25 | 3.75 |

This example shows that alkylsulfonic acid developer solutions based on both water and polar organic solvents can be effectively used to develop organometallic photoresist line space patterns. It also shows that low alkylsulfonic acid composition concentrations of about 0.05 M can be sufficient or even preferable and suggests that even lower concentrations can be used to develop high quality line space patterns. It also indicates that alkylsulfonic acid-based developer solutions are effective in preferentially removing non-irradiated regions of organometallic photoresist material during negative tone development in an EUV patterning process.

### Example 6: High Contrast Behavior of Alkylsulfonic Acid Developer Solutions in an EUV Exposure and Development Process

Photoresist films of approximately 22 nm thickness were deposited by spin coating an organotin photoresist blend having an 80:20 molar ratio of tert-butyltin tris(tert-amyloxide) and methyltin tris(tert-amyloxide) onto three silicon wafers E, F, and G. The Si wafers were previously coated with about an approximately 9 nm thick spin-on-glass underlayer. Following coating of the prepared Si wafers with the organotin photoresist, the wafers were subjected to a post-application bake (PAB) at 100° C. for 60 s and then exposed to 13.5 nm EUV radiation using an ASML NXE3400 exposure tool to produce a contrast array, e.g., an array of pads across each wafer, each pad having been exposed to a different dose of EUV radiation from about 2 mJ/cm² to about 100 mJ/cm². The wafers were then subjected to a 180° C. post exposure bake (PEB) before being developed with one of three developer solutions in a negative tone process. Development was conducted by dispensing the developer solution onto the wafer, allowing the developer solution to contact the exposed coating, and finally rapidly rotating the wafer to remove the solution after thirty seconds had elapsed from dispensing.

Wafer E was developed using a solution of 5% acetic acid by weight (0.87 M) in propylene glycol methyl ether acetate (PGMEA). Wafers F and G were developed with an alkylsulfonic acid based developer solution comprising water as a solvent and methanesulfonic acid (MSA) at a concentration of 0.05 M and 0.10 M for wafers F and G, respectively. Following development, the wafers were subjected to a 250° C. hard bake for 60 seconds. The thickness of each pad was then determined using ellipsometry and contrast curves were generated for each wafer by plotting the remaining film thickness for each pad as a function of the radiation dose that the pad received.

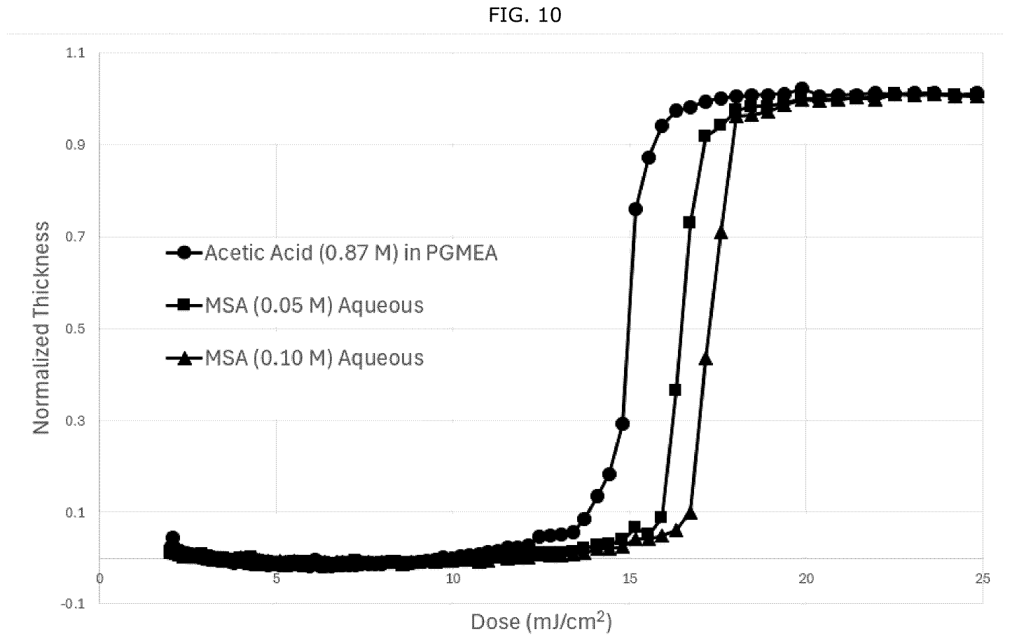

The generated contrast curves are shown in FIG. 10. Visual observation of the curves indicates a reduced area of the footer region for samples F and G in comparison to sample E. This suggests that the alkylsulfonic acid developer solutions can be effective in reducing the amount of residual under-exposed material which can manifest as scum and/or bridging defects during patterning. Values of both contrast (γ) and dose-to-gel (D_{g}) were calculated as:

$$γ = \frac{1}{ln ( \frac{{D}_{g}}{{D}_{0}} )}$$

wherein D_{g} is the dose at which a line tangent to the point of maximum slope on the normalized resist thickness versus log (Dose) curve reaches a normalized thickness value of 1.0. Similarly, D₀ is the dose at which the same tangent line reaches a normalized thickness value of 0. These values are presented in Table 5.

TABLE 5

| | | D_{g} | Contrast |
|---|---|---|---|
| Sample | Developer Solution | (mJ/cm²) | (γ) |
| E | 0.87M Acetic Acid | 15.59 | 11.68 |
| | in PGMEA | | |
| F | 0.05M MSA in H₂O | 16.99 | 15.45 |
| G | 0.10M MSA in H₂O | 17.88 | 14.29 |

The calculated values indicate that developer solutions based on methane sulfonic acid exhibit higher contrast behavior than acetic acid in PGMEA, which has been identified as a preferable developer solution based on performance characteristics. The acetic acid based developer showed a contrast of 11.68, while the methanesulfonic acid based developers showed contrast values about 3.77 and 2.61 higher for concentrations of 0.05 M and 0.10 M, respectively. In other words, the methanesulfonic acid developer showed a smaller dose window in which the photoresist is changed from substantially soluble to substantially insoluble in the developer solution. The dose window for the 0.05 M and 0.10 M MSA developer solutions were approximately 16.8% and 5.5% smaller, respectively, than that of the acetic acid based developer. The contrast is surprisingly high and the unique behavior of alkylsulfonic acid based developer solutions suggest the effective application as a high contrast developer solutions for photolithography processes.

### Further Inventive Concepts

A1. A method for patterning an organometallic material having a latent image formed by irradiation on a substrate, the method comprising:
heating the organometallic material at a temperature from about 45° C. to about 250° C. to perform a post exposure bake; and
contacting the organometallic material with an alkylsulfonic acid developer solution comprising a solvent and an alkylsulfonic acid composition dissolved in the solvent.

A2. The method of inventive concept A1 wherein the heating to perform a post exposure bake is conducted for a period of time from about 0.1 minutes to about 30 minutes.

A3 The method of inventive concept A1 further comprising, after the contacting step, heating the organometallic material at a temperature from about 45° C. to about 400° C. to perform a hard bake.

A4. The method of inventive concept A3 wherein the heating to perform a hard bake is conducted for a period of time from about 0.1 minutes to about 30 minutes.

A5. The method of inventive concept A1 further comprising, after the heating to perform a post exposure bake and prior to the contacting step,
resting the organometallic material at ambient temperature for a selected period of time from about 30 seconds to about 30 minutes; and
after resting, heating the organometallic material at a temperature from about 45° C. to about 250° C. to perform second post exposure bake.

A6. The method of inventive concept A5 wherein the heating to perform a second post exposure bake is conducted for a period of time from about 0.1 minutes to about 30 minutes.

A7. The method of inventive concept A1 further comprising, after the heating step and prior to the contacting step,
developing the organometallic material with a first developer solution to form a developed structure; and
heating the developed structure at a temperature from about 45° C. to about 250° C. to perform a post development bake.

A8. The method of inventive concept A7 wherein the first developer solution comprises an organic solvent.

A9. The method of inventive concept A7 wherein the first developer solution comprises PGMEA with acetic acid at a concentration from about 0.1% to about 10% by weight.

A10. The method of inventive concept A1 wherein the substrate comprises Si.

A11. The method of inventive concept A1 wherein the alkylsulfonic acid composition comprises an alkylsulfonic acid represented by the formula R¹SO³H where R¹ is a linear, branched, cyclic, or aromatic alkyl group having from 1 to 10 carbons and optionally at least one H replaced by F.

A12. The method of inventive concept A1 wherein the alkylsulfonic acid composition comprises methanesulfonic acid.

A13. The method of inventive concept A1 wherein the solvent comprises water.

A14. The method of inventive concept A1 wherein the solvent comprises a polar organic solvent.

A15. The method of inventive concept A1 wherein the alkylsulfonic acid developer solution has a concentration of the alkylsulfonic acid composition from about 0.001 M to about 1.0 M.

A16. The method of inventive concept A1 further comprising, prior to the heating to perform a post exposure bake, exposing an organometallic coated substrate to a pattern of EUV radiation to form the latent image, wherein the latent image comprises exposed and unexposed regions.

B1. A method for improving a pattern formed in an organometallic material, the method comprising:
descumming a patterned organometallic material on a substrate surface with a developer solution to reduce defectivity of the pattern, wherein the developer solution comprises a solvent and an alkylsulfonic acid composition dissolved in the solvent.

B2. The method of inventive concept B1 wherein the alkylsulfonic acid composition comprises an alkylsulfonic acid represented by the formula R¹SO³H where R¹ is a linear, branched, cyclic, or aromatic alkyl group having from 1 to 10 carbons and optionally at least one H replaced by F.

B3. The method of inventive concept B2 wherein the alkylsulfonic acid comprises methanesulfonic acid, ethanesulfonic acid, propanesulfonic acid, propane-2-sulfonic acid, p-toluene sulfonic acid, benzene sulfonic acid, triflic acid, or a combination thereof.

B4. The method of inventive concept B2 wherein the alkylsulfonic acid composition further comprises a second alkylsulfonic acid represented by the formula R²SO³H where R² is a linear, branched, cyclic, or aromatic alkyl group having from 1 to 10 carbons and optionally at least one H replaced by F, and wherein R² is different from R¹.

B5. The method of inventive concept B1 wherein the solvent comprises water.

B6. The method of inventive concept B1 wherein the solvent comprises a polar organic solvent.

B7. The method of inventive concept B6 wherein the polar organic solvent is an alcohol, a combination of alcohols, an ether, an ester, a ketone, or a combination thereof.

B8. The method of inventive concept B1 wherein the developer solution has a concentration of the alkylsulfonic acid composition from about 0.001 M to about 3.0 M.

B9. The method of inventive concept B1 wherein the descumming step comprises submerging the organometallic material in the developer solution or dispensing the developer solution on the organometallic material.

B10. The method of inventive concept B1 wherein the descumming step is performed for about 5 seconds to about 10 minutes.

B11. The method of inventive concept B1 wherein the descumming step is performed for no more than about 2 minutes.

B12. The method of inventive concept B1 wherein the patterned organometallic material is the product of a dry development process.

B13. The method of inventive concept B1 further comprising, prior to the descumming step, dry developing an organometallic material to form the patterned organometallic material.

B14. The method of inventive concept B1 wherein the patterned organometallic material is the product of a first liquid development process comprising an organic solvent.

B15. The method of inventive concept B1 further comprising, prior to the rinsing step, contacting an organometallic material with a negative tone developer to form the patterned organometallic material.

B16. The method of inventive concept B14 wherein the organic solvent comprises 2-heptanone.

B17. The method of inventive concept B1 wherein the patterned organometallic material comprises an organotin material.

B18. The method of inventive concept B17 wherein the organotin material comprises an organotin oxo-hydroxo composition having organo ligands R attached to Sn via radiation sensitive Sn—C bonds, wherein R comprises an organo group having from 1 to 31 carbons atoms, optionally substituted with one or more heteroatom functional groups.

C1. A patterning solution system comprising:
a first patterning solution comprising an organic solvent; and
a second patterning solution comprising a second solvent and an alkylsulfonic acid.

C2. The patterning solution system of inventive concept C1 wherein the organic solvent is an aromatic compounds, an ester, an alcohol, a ketone, an ether, or mixture thereof.

C3. The patterning solution system of inventive concept C1 wherein the organic solvent comprises benzene, xylenes, toluene, propylene glycol monomethyl ester acetate (PGMEA), ethyl acetate, ethyl lactate, n-butyl acetate, butyrolactone), 4-methyl-2-pentanol, 1-butanol, isopropanol, 1-propanol, methanol, methyl ethyl ketone, acetone, cyclohexanone, 2-heptanone, 2-octanone, tetrahydrofuran, dioxane, anisole, or mixtures thereof.

C4. The patterning solution system of inventive concept C1 wherein the second solvent is aqueous.

C5. The patterning solution system of inventive concept C1 wherein the alkylsulfonic acid is represented by the formula R¹SO³H where R¹ is a linear, branched, cyclic, or aromatic alkyl group having from 1 to 10 carbons and optionally at least one H replaced by F.

C6. The patterning solution system of inventive concept C1 wherein the second patterning solution has a concentration of the alkylsulfonic acid composition from about 0.001 M to about 1.0 M.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to expected uncertainties in the associated values as would be understood in the particular context by a person of ordinary skill in the art.

What is claimed is:

1. A method of developing an organometallic material on a surface of a substrate and having a virtual image, the method comprising contacting the organometallic material with an alkylsulfonic acid developer solution comprising an alkylsulfonic acid composition and a solvent.

2. The method of claim 1 wherein the organometallic material comprises exposed regions and un-exposed regions forming the virtual image.

3. The method of claim 2 wherein the unexposed regions are preferentially removed relative to the exposed regions by contacting the organometallic material with the alkylsulfonic acid developer solution relative to the exposed regions.

4. The method of claim 1 wherein the organometallic material has an initial pattern with regions of irradiated organometallic material and regions substantially devoid of organometallic material exposing the substrate surface and wherein the contacting results in a descummed pattern with higher contrast relative to the initial pattern.

5. The method of claim 4 wherein the pattern is formed by development with a liquid developer.

6. The method of claim 4 wherein the pattern is formed using dry development.

7. The method of claim 1 wherein the organometallic material comprises an organotin material.

8. The method of claim 7 wherein the organotin material comprises an organotin oxo-hydroxo composition having organo ligands R attached to Sn via radiation sensitive Sn—C bonds, wherein R comprises an alkyl group having from 1 to 31 carbons atoms, optionally substituted with one or more heteroatom functional groups and optionally comprising one or more unsaturated or aromatic moieties.

9. The method of claim 8 wherein R is a linear alkyl, a branched alkyl, a cycloalkyl, or combinations thereof.

10. The method of claim 8 wherein R is methyl, ethyl, n-propyl, isopropyl, n-butyl, t-butyl, isobutyl, t-amyl, propenyl, butenyl, pentenyl, or isomers thereof, or combinations thereof.

11. The method of claim 8 wherein R comprises two or more different alkyl groups.

12. The method of claim 8 wherein the one or more heteroatom functional group comprises O, S, N, Si, Ge, Sn, Te, halogen atoms, or a combination thereof.

13. The method of claim 8 wherein the one or more heteroatom functional group comprises a cyano, a thio, a silyl, an ether, a keto, an ester, a halogenated group, a group containing Ge, Sn, or Te, or a combination thereof.

14. The method of claim 2 wherein the method is a negative tone development process.

15. The method of claim 1 wherein the alkylsulfonic acid composition comprises an alkylsulfonic acid represented by the formula R¹SO³H where R¹ is a linear, branched, cyclic, or aromatic alkyl group having from 1 to 10 carbons and optionally at least one H replaced by F.

16. The method of claim 1 wherein the alkylsulfonic acid composition comprises a fluorinated alkylsulfonic acid.

17. The method of claim 1 wherein the alkylsulfonic acid composition comprises methanesulfonic acid, ethanesulfonic acid, propanesulfonic acid, propane-2-sulfonic acid, p-toluene sulfonic acid, benzene sulfonic acid, triflic acid, or a combination thereof.

18. The method of claim 1 wherein the alkylsulfonic acid composition further comprises a second alkylsulfonic acid represented by the formula R²SO³H where R² is a linear, branched, cyclic, or aromatic alkyl group having from 1 to 10 carbons and optionally at least one H replaced by F, and wherein R² is different from R¹.

19. The method of claim 1 wherein the solvent comprises water.

20. The method of claim 1 wherein the solvent comprises a polar organic solvent.

21. The method of claim 20 wherein the polar organic solvent is an alcohol, an ether, an ester, a ketone, or a combination thereof.

22. The method of claim 20 wherein the polar organic solvent comprises PGMEA.

23. The method of claim 1 wherein the alkylsulfonic acid developer solution has a concentration of the alkylsulfonic acid composition from about 0.001 M to about 3.0 M.

24. The method of claim 1 wherein the contacting step comprises submerging the organometallic material in the alkylsulfonic acid developer solution.

25. The method of claim 1 wherein the contacting step comprises dispensing the alkylsulfonic acid developer solution on the organometallic material.

26. The method of claim 1 wherein the method comprises a puddle development process.

27. The method of claim 1 wherein the contacting step is performed for from about 5 seconds to about 10 minutes to form a developed organometallic material.

28. The method of claim 1 wherein the contacting step is performed for from about 10 seconds to about 5 minutes.

29. The method of claim 27 further comprising rinsing the developed organometallic material with a rinsing composition.

30. The method of claim 29 wherein the rinsing composition comprises water, an inert gas, or a combination thereof.

31. The method of claim 1 further comprising, before the contacting step, baking the organometallic material at a temperature from about 45° C. to about 250° C. for about 0.1 minutes to about 30 minutes.

32. The method of claim 31 further comprising, after the baking step, resting the organometallic material for a selected period of time from about 30 seconds to about 1 hour prior to the contacting step.

33. The method of claim 32 further comprising, after the resting step, baking the organometallic material at a temperature from about 45° C. to about 250° C. for about 0.1 minutes to about 30 minutes.

34. The method of claim 1 further comprising, after the contacting step, baking the organometallic material at a temperature from about 45° C. to about 400° C. for about 0.1 minutes to about 30 minutes.
